(19) United States
(12) Patent Application Publication
(10) Pub. No.: US 2025/0380587 A1
(43) Pub. Date: Dec. 11, 2025

(54) DISPLAY APPARATUS

(71) Applicant: LG Display Co., Ltd., Seoul (KR)

(72) Inventors: Yeongyeong BAE, Paju-si (KR); Soonsung AHN, Paju-si (KR)

(73) Assignee: LG Display Co., Ltd., Seoul (KR)

(21) Appl. No.: 19/229,687

(22) Filed: Jun. 5, 2025

(30) Foreign Application Priority Data
Jun. 11, 2024 (KR) 10-2024-0075449

(51) Int. Cl. H10K 59/131; G09G 3/3233; H10K 59/88

(52) U.S. Cl. CPC H10K 59/131; G09G 3/3233; H10K 59/88; G09G 2300/0413; G09G 2300/0426; G09G 2300/0819; G09G 2300/0842; G09G 2300/0861; G09G 2320/0247; G09G 2330/021; G09G 2340/0435

(57) ABSTRACT

A display apparatus includes a display area configured to display an image, and a non-display area adjacent to the display area. The display apparatus includes a pixel disposed in the display area, the pixel including an anode electrode, an anode reset line configured to reset the anode electrode. The display apparatus further includes a dummy line disposed in the display area. The anode reset line is electrically connected to the dummy line. The dummy line may include multiple lines formed in horizontal and vertical directions and may be positioned on the same layer as other signal lines, enabling effective reuse of existing conductive layers. By electrically connecting the anode reset line to the dummy line, the apparatus can form a mesh-like structure that distributes the anode reset voltage more uniformly across the display area, thereby reducing ripple and improving image quality without requiring additional processing steps.

### CROSS REFERENCE TO RELATED APPLICATION

The present application claims priority to Korean Patent Application No. 10-2024-0075449, filed Jun. 11, 2024, the entire contents of which is incorporated herein for all purposes by this reference.

### BACKGROUND

### Technical Field

The present specification relates to a display apparatus.

### Description of the Related Art

As the information society develops, various demands for display apparatuses for displaying images are increasing, and various types of display apparatuses such as liquid crystal display (LCD) apparatuses and organic light emitting diode (OLED) display apparatuses are utilized.

Images displayed on a display apparatus may be still images or moving images, and the moving image may include various types such as sports images, game images, and movies. The display apparatus is driven in a variable refresh rate (VRR) mode in which a driving frequency varies depending on the type of an image, thereby reducing power consumption and extending the lifetime of the display apparatus.

### BRIEF SUMMARY

The inventors of the present disclosure address key challenges in Variable Refresh Rate (VRR) operation, particularly ripple and voltage instability in anode reset lines, which can degrade image quality. Prior approaches in the related art to reduce line resistance-such as adding separate low-resistance metal lines-encounter constraints due to layout limitations (especially in oxide TFT structures that require shielding) and result in increased process complexity and cost. Various embodiments disclosed herein solve these technical problems by repurposing existing dummy lines within the display panel as part of the anode reset network. By electrically connecting these non-functional lines to the anode reset line, the design reduces overall resistance without requiring additional routing or fabrication steps. This approach not only stabilizes the anode reset voltage for improved image fidelity, but also enhances layout design flexibility and reduces power consumption during reset operations, all while maintaining manufacturing simplicity.

For example, some embodiments of the present specification is directed to providing a display apparatus in which it is possible to improve image quality abnormality due to a change in anode reset voltage by reducing a resistance of an anode reset line.

Some embodiments of the present specification is also directed to providing a display apparatus having the high degree of freedom in designing a layout using a non-used dummy line.

Some embodiments of the present specification is also directed to providing a display apparatus in which it is possible to omit a process for forming a separate low-resistance line.

Some embodiments of the present specification is also directed to providing a display apparatus in which it is possible to implement a narrow bezel by connecting a data driving unit to a data line through a connection line in a display area.

Technical benefits of the present specification are not limited to the above-described benefits, and other technical benefits may be inferred from the following embodiments.

According to one embodiment, there is provided a display apparatus including a display area on which an image is displayed, and a non-display area located around the display area, which includes a pixel disposed in the display area and including an anode electrode, an anode reset line that resets the anode electrode, and a dummy line, wherein the anode reset line is electrically connected to the dummy line.

According to another embodiment, there is provided a display apparatus including a display area having a pixel including an anode electrode, and a non-display area located around the display area, which includes a substrate, a first conductive layer including an anode reset line that resets the anode electrode, and a second conductive layer disposed on the first conductive layer and including a vertical dummy line electrically connected to the anode reset line.

Detailed matters of other embodiments are included in detailed description and accompanying drawings.

### BRIEF DESCRIPTION OF THE SEVERAL VIEWS OF THE DRAWINGS

FIG. 1 is a schematic block diagram illustrating a display apparatus according to one embodiment.

FIG. 2 is a cross-sectional view illustrating a stacked form of the display apparatus according to one embodiment.

FIG. 3 is a view illustrating a pixel circuit in the display apparatus according to one embodiment.

FIG. 4 is a waveform diagram illustrating a ripple phenomenon of an anode reset voltage.

FIG. 5 is a plan view illustrating a display panel and a printed circuit board according to one embodiment.

FIG. 6 is an enlarged plan view of a part of the display panel according to one embodiment.

FIG. 7 is a cross-sectional view of portion Q1 of FIG. 6 taken in a first direction.

FIG. 8A is a schematic plan view illustrating a part of the display panel of the display apparatus according to a comparative example.

FIG. 8B is a schematic plan view illustrating a part of the display panel of the display apparatus according to one embodiment.

FIG. 9 is an enlarged plan view of a part of a display panel of a display apparatus according to another embodiment.

FIG. 10A is a view illustrating the display apparatus according to a comparative example, and FIG. 10B is a view illustrating the display apparatus according to another embodiment.

FIG. 11 is an enlarged plan view of a part of a display panel of a display apparatus according to still another embodiment.

FIG. 12 is a cross-sectional view of portion Q2 of FIG. 11 taken in a second direction.

FIG. 13 is a cross-sectional view illustrating a stacked form of the display apparatus according to still another embodiment.

FIG. 14 is a view illustrating a pixel circuit in the display apparatus according to still another embodiment.

FIG. 15 is a cross-sectional view illustrating a connecting portion of an anode reset line and a dummy vertical connection line of the display apparatus according to still another embodiment.

### DETAILED DESCRIPTION

Hereinafter, embodiments will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween. That is, the term “connected” is intended to have the broadest possible meaning. Specifically, the phrase “A is connected to B” encompasses both a direct connection—where no intervening components or elements are present—and an indirect connection, where one or more intermediate components or elements exist between A and B. For example, “A is connected to B” includes both direct physical or electrical coupling and indirect coupling through one or more intervening components. Unless explicitly stated otherwise, these terms do not require direct physical or electrical contact. The terms “coupled,” “in contact” should be interpreted in the same manner.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

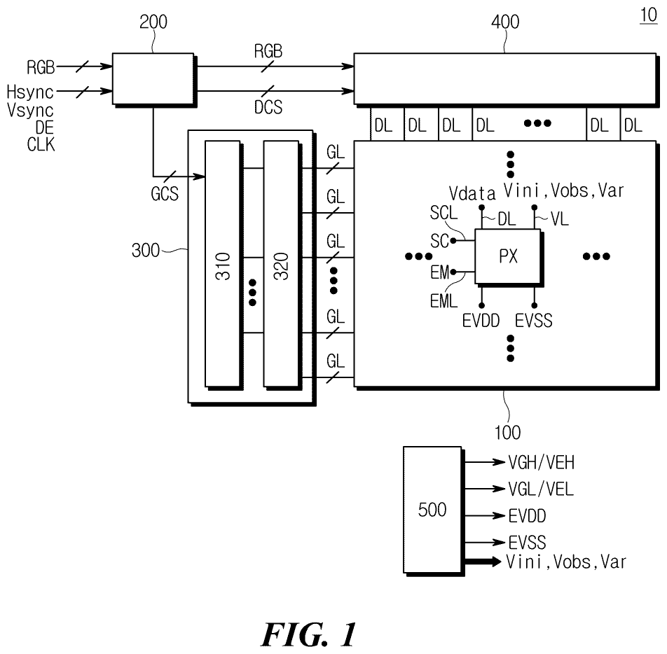

FIG. 1 is a schematic block diagram illustrating a display apparatus according to one embodiment.

Referring to FIG. 1, a display apparatus 10 includes a display panel 100 including a plurality of pixels PX, a controller 200, a gate driving unit 300 for supplying a gate signal to each of the plurality of pixels PX, a data driving unit 400 for supplying a data signal to each of the plurality of pixels PX, and a power supply unit 500 for supplying power required for driving to each of the plurality of pixels PX.

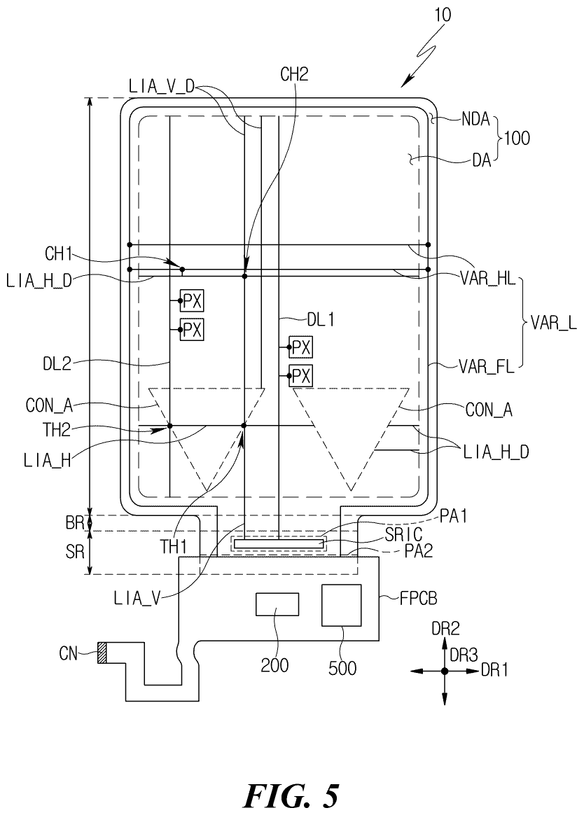

The display panel 100 includes a display area DA (see FIG. 5) in which the pixel PXs is positioned and a non-display area NDA (see FIG. 5) which is disposed to surround the display area DA and in which the gate driving unit 300 and the data driving unit 400 are disposed.

In the display panel 100, a plurality of gate lines GL and a plurality of data lines DL intersect each other, and each of the plurality of pixels PX is connected to the gate line GL and the data line DL. Specifically, one pixel PX receives gate signals from the gate driving unit 300 through the gate line GL, receives data signals from the data driving unit 400 through the data line DL, and receives a high-potential driving voltage EVDD and a low-potential driving voltage EVSS from the power supply unit 500.

Here, a scan signal SC and a light-emitting control signal EM are supplied through the gate line GL, and a data voltage Vdata is supplied through the data line DL. In addition, according to various embodiments, the gate line GL may include a plurality of scan lines SCL through which the scan signal SC is supplied and a light-emitting control signal line EML through which the light-emitting control signal EM is supplied. In addition, the plurality of pixels PX additionally include a power line VL to receive a bias voltage Vobs and initialization voltages Var and Vini.

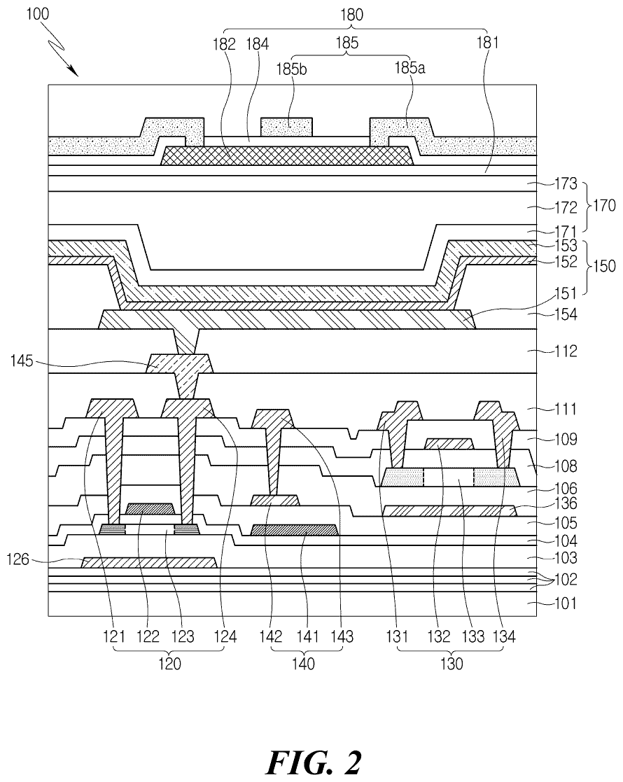

In addition, as illustrated in FIG. 2, each of the pixels PX includes a light-emitting element 150 (also referred to as “EL”) and a pixel circuit for controlling the driving of the light-emitting element EL. Here, the light-emitting element EL includes anode electrode 151, a cathode electrode 153, and an organic layer 152 between the anode electrode 151 and the cathode electrode 153.

The pixel circuit includes a plurality of switching elements, a driving element, and a capacitor. Here, the switching element and the driving element may be formed of thin film transistors. In the pixel circuit, the driving element adjusts the amount of light emitted from the light-emitting element EL by controlling the amount of current supplied to the light-emitting element EL according to the data voltage. In addition, the plurality of switching elements operate the pixel circuit after receiving the scan signals SC supplied through the plurality of scan lines SCL and the light-emitting control signal EM supplied through the light-emitting control signal line EML.

The display panel 100 may be implemented as a non-transmissive display panel or a transmissive display panel. The transmissive display panel may be applied to a transparent display apparatus in which images are displayed on a screen and a real object in the background is visible. The display panel 100 may be manufactured as a flexible display panel. The flexible display panel may be implemented as an organic light emitting diode (OLED) panel using a plastic substrate.

Each of the pixels PX may be divided into a red pixel, a green pixel, and a blue pixel to implement colors. The each of the pixel PX may further include a white pixel. The each of the pixels PX includes the pixel circuit.

Touch sensors may be disposed on the display panel 100. A touch input may be sensed using separate touch sensors or sensed through the pixels PX. The touch sensors are on-cell type or add-on type touch sensors and may be implemented as in-cell type touch sensors disposed on the screen of the display panel or embedded into the display panel 100.

The controller 200 processes image data RGB input from the outside according to the size and resolution of the display panel 100 and supplies the processed image data RGB to the data driving unit 400. The controller 200 generates a gate control signal GCS and a data control signal DCS using synchronization signals, for example, a dot clock signal CLK, a data enable signal DE, a horizontal synchronization signal Hsync, and a vertical synchronization signal Vsync, received from the outside. The controller 200 controls the gate driving unit 300 and the data driving unit 400 by supplying the generated gate control signal GCS and data control signal DCS to the gate driving unit 300 and the data driving unit 400, respectively.

The controller 200 may be configured by being coupled to various processors, such as a microprocessor, a mobile processor, an application processor, etc., according to a device to be mounted.

A host system may be one of a television (TV) system, a set-top box, a navigation system, a personal computer (PC), a home theater system, a mobile device, a wearable device, and a vehicle system.

The controller 200 generates signals so that the pixel PX is driven at various refresh rates. That is, the controller 200 generates driving-related signals so that the pixel PX is driven in a variable refresh rate (VRR) mode or to be switched between a first refresh rate and a second refresh rate. For example, the controller 200 may drive the pixel PX at various refresh rates by simply changing rates of clock signals, generating synchronization signals to generate a horizontal blank or a vertical blank, or driving the gate driving unit 300 in a mask manner.

The controller 200 generates the gate control signal GCS for controlling an operation timing of the gate driving unit 300 and the data control signal DCS for controlling an operation timing of the data driving unit 400 based on timing signals Vsync, Hsync, and DE received from the host system. The controller 200 synchronizes the gate driving unit 300 and the data driving unit 400 by controlling an operation timing of a display panel driving unit.

A voltage level of the gate control signal GCS output from the controller 200 may be converted into gate-on voltages VGL and VEL and gate-off voltages VGH and VEH through a level shifter (not illustrated) and supplied to the gate driving unit 300. The level shifter converts a low level voltage of the gate control signal GCS into a gate low voltage VGL and converts a high level voltage of the gate control signal GCS into a gate high voltage VGH. The gate control signal GCS includes a start pulse and a shift clock.

The gate driving unit 300 supplies the scan signal SC to the gate line GL according to the gate control signal GCS supplied from the controller 200. The gate driving unit 300 may be disposed at one side or both sides of the display panel 100 by a gate in panel (GIP) method.

The gate driving unit 300 sequentially outputs the gate signals to the plurality of gate lines GL under the control of the controller 200. The gate driving unit 300 may shift the gate signals using the shift register to sequentially supply the signals to the gate lines GL.

The gate signals may include the scan signal SC and the light-emitting control signal EM in an OLED display apparatus. The scan signal SC includes a scan pulse that swings between the gate-on voltage VGL and the gate-off voltage VGH. The light-emitting control signal EM may include a light-emitting control signal pulse that swings between the gate-on voltage VEL and the gate-off voltage VEH.

The scan pulse is synchronized with the data voltage Vdata to select pixels PX in a line on which data is written. The light-emitting control signal EM defines light-emitting times of the pixels P.

The gate driving unit 300 may include a light-emitting control signal driver 310 and at least one scan driver 320.

The light-emitting control signal driver 310 outputs the light-emitting control signal pulse in response to the start pulse and the shift clock output from the controller 200 and sequentially shifts the light-emitting control signal pulse according to the shift clock.

The at least one scan driver 320 outputs the scan pulse in response to the start pulse and the shift clock output from the controller 200 and shifts the scan pulse according to a shift clock timing.

The data driving unit 400 converts the image data RGB into the data voltage Vdata according to the data control signal DCS supplied from the controller 200 and supplies the converted data voltage Vdata to the pixel PX through the data line DL.

FIG. 1 illustrates the data driving unit 400 disposed at one side of the display panel 100 as a single data driving unit, but the number and arrangement location of the data driving unit 400 are not limited thereto.

That is, the data driving unit 400 may be composed of a plurality of integrated circuits (IC) and disposed separately as a plurality of data driving units at one side of the display panel 100.

The power supply unit 500 generates DC power required for driving a pixel array and the display panel driving unit of the display panel 100 using a DC-DC converter. The DC-DC converter may include a charge pump, a regulator, a buck converter, a boost converter, etc.

The power supply unit 500 may receive a DC input voltage applied from the host system (not illustrated) and generate DC voltages, such as the gate-on voltages VGL and VEL, the gate-off voltages VGH and VEH, the high-potential driving voltage EVDD, the low-potential driving voltage EVSS, the bias voltage Vobs, the initialization voltages Var and Vini, etc. The gate-on voltages VGL and VEL and the gate-off voltages VGH and VEH are supplied to the level shifter (not illustrated) and the gate driving unit 300. The high-potential driving voltage EVDD and the low-potential driving voltage EVSS are supplied to the pixels PX. The bias voltage Vobs and the initialization voltages Var and Vini are supplied to the pixels PX through the power line VL. The power line VL may include an anode reset line VAR_L (see FIG. 5) to be described below.

FIG. 2 is a cross-sectional view illustrating a stacked form of the display apparatus according to one embodiment.

Referring to FIG. 2, the display panel 100 may include a substrate 101, a first thin film transistor 120, a second thin film transistor 130, a light-emitting element EL, an encapsulation part 170, and a touch part 180.

The substrate 101 may include one or more plastic materials. For example, the substrate 101 may be a multi-substrate including a plurality of plastic materials, such as polyimide, but the embodiments of the present specification are not limited thereto.

A buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

A first light-shielding layer 126 may be disposed on the buffer layer 102. The first light-shielding layer 126 can prevent light from transmitting a first semiconductor layer 123 of the first thin film transistor 120. For example, the first semiconductor layer 123 may be disposed to overlap the first light-shielding layer 126. The first light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

A first insulating layer 103 may be disposed on the first light-shielding layer 126. The first insulating layer 103 can prevent a short circuit between a component of the first thin film transistor 120 and the first light-shielding layer 126. The first insulating layer 103 may be formed of the same material as the buffer layer 102, but the embodiments of the present specification are not limited thereto. For example, the first insulating layer 103 may be formed of an inorganic material, such as silicon nitride (SiNₓ) or silicon oxide (SiOₓ), but the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

A second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but the embodiments of the present specification are not limited thereto. The first gate electrode 122 may be disposed along with a gate line.

A third insulating layer 105 may be disposed on the first gate electrode 122. The third insulating layer 105 may be formed of the same material as the first insulating layer 103 or the second insulating layer 104, but the embodiments of the present specification are not limited thereto.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be formed of a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first source electrode 121 and the first drain electrode 124 may be disposed along with a data line DL. For example, the data line DL may be formed of the same material as the first source electrode 121 and the first drain electrode 124 and formed on the same layer as the first source electrode 121 and the first drain electrode 124, but the embodiments of the present specification are not limited thereto.

A storage electrode 140 may be disposed to be spaced apart from the first thin film transistor 120. The storage electrode 140 may include a first storage electrode 141, a second storage electrode 142, and a third storage electrode 143.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 can prevent light from traveling to the second semiconductor layer 133 similar to the first light-shielding layer 126, thereby extending the life of the second thin film transistor 130. For example, the second semiconductor layer 133 may be disposed to overlap the second light-shielding layer 136.

A fourth insulating layer 106 may be disposed on the second light-shielding layer 136. The fourth insulating layer 106 may be formed of the same material as the first insulating layer 103, the second insulating layer 104, or the third insulating layer 105, but the embodiments of the present specification are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

A fifth insulating layer 108 may be disposed on the second semiconductor layer 133. The fifth insulating layer 108 may be formed of the same material as the first insulating layer 103, the second insulating layer 104, the third insulating layer 105, or the fourth insulating layer 106, but the embodiments of the present specification are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto.

A sixth insulating layer 109 may be disposed on the second gate electrode 132. The sixth insulating layer 109 may be formed of the same material as the first insulating layer 103, the second insulating layer 104, the third insulating layer 105, the fourth insulating layer 106, or the fifth insulating layer 108, but the embodiments of the present specification are not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as the first source electrode 121 and the first drain electrode 124 and disposed on the same layer as the first source electrode 121 and the first drain electrode 124, but the embodiments of the present specification are not limited thereto. For example, the third storage electrode 143, the second source electrode 131, and the second drain electrode 134 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The first thin film transistor 120 may be a driving transistor, and the second thin film transistor 130 may be a switching transistor, but the embodiments of the present specification are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material containing an acrylic resin, an epoxy resin, a phenolic resin, a polyamide resin, or a polyimide resin, but the embodiments of the present specification are not limited thereto.

A second protective layer 112 may be disposed on the first protective layer 111. The second protective layer 112 may be formed of the same material as the first protective layer 111, but the embodiments of the present specification are not limited thereto.

A connection electrode 145 may be disposed between the first protective layer 111 and the second protective layer 112.

The connection electrode 145 may electrically connect the first thin film transistor 120 to the light-emitting element EL. The connection electrode 145 may be formed of the same material as the first source electrode 121 and the first drain electrode 124, but the embodiments of the present specification are not limited thereto.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The light-emitting element EL may be disposed on the second protective layer 112. The light-emitting element EL may include the anode electrode 151, the organic layer 152, and the cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but the embodiments of the present specification are not limited thereto. The anode electrode 151 may include a metallic material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and may be formed of a single layer or multiple layers, but the embodiments of the present specification are not limited thereto.

The organic layer 152 may be disposed on the anode electrode 151. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto. The organic layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto. For example, the organic layer 152 of the display panel 100 according to one embodiment of the present specification may include the organic light-emitting layer. The organic layer 152 may include a red light-emitting layer, a green light-emitting layer, and a blue light-emitting layer. The organic layer 152 may be a white light-emitting layer, but the embodiments of the present specification are not limited thereto.

The cathode electrode 153 may be disposed on the organic layer 152. The cathode electrode 153 may be a transparent electrode that transmits light, but the embodiments of the present specification are not limited thereto. For example, the cathode electrode 153 may include a transparent conductive material, such as indium tin oxide (ITO) or indium zinc oxide (IZO), or a metal that transmits visible light, but the embodiments of the present specification are not limited thereto.

A bank 154 may be disposed to expose the anode electrode 151. The bank 154 may define an opening (or a light-emitting area) of a sub-pixel and may be disposed to cover an edge portion of the anode electrode 151. Each sub-pixel may include a red light-emitting area, a green light-emitting area, and a blue light-emitting area. For example, the sub-pixel may be a pixel, but is not limited by the term. The bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be a black bank. When the bank 154 is formed of a material containing black pigment or black dye, it is possible to shield external light or light reflected from the outside, thereby further increasing the luminance of the display apparatus. A spacer may be further disposed on the bank 154. The spacer may be formed of the same material as the bank 154, but the embodiments of the present specification are not limited thereto.

The encapsulation part 170 may be disposed above the bank 154 or the light-emitting element EL. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present specification are not limited thereto.

A buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present specification are not limited thereto. An insulating layer 184 may be disposed on the touch buffer layer 181. The insulating layer 184 can prevent a short circuit between touch electrodes. The insulating layer 184 may be formed of silicon oxide (SiOₓ), silicon nitride (SiNₓ), or multiple layers thereof, but the embodiments of the present specification are not limited thereto. A first touch electrode 185 may be disposed on the insulating layer 184. The first touch electrode 185 may include a la touch electrode 185a extending in a first direction and a 1b touch electrode 185b extending in a second direction that differs from the first direction.

A second touch electrode 182 may be disposed between the buffer layer 181 and the insulating layer 184.

The second touch electrode 182 may be electrically connected to the 1a touch electrode 185a through a contact hole formed in the insulating layer 184. For example, the 1a touch electrode 185a and the second touch electrode 182 may extend in the first direction.

The first touch electrode 185 and the second touch electrode 182 may include a metallic material. For example, the first touch electrode 185 and the second touch electrode 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

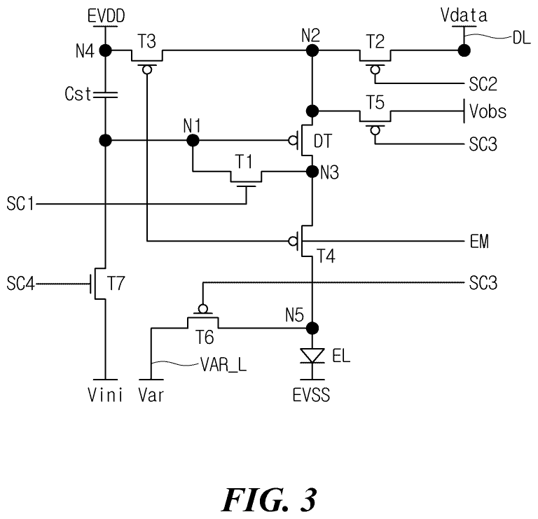

FIG. 3 is a view illustrating a pixel circuit in the display apparatus according to one embodiment.

FIG. 3 exemplarily illustrates the pixel circuit for description, and the embodiments of the present specification are not limited thereto as long as the pixel circuit has a structure that may control the light-emission of the light-emitting element EL by receiving the light-emitting signal EM. For example, the pixel circuit may include an additional scan signal, a switching thin film transistor connected to the additional scan signal, and a switching thin film transistor to which an additional initialization voltage is applied, and a connection relationship between the switching elements or a connection location of a capacitor may be disposed in various ways. Hereinafter, for convenience of description, a display apparatus having the pixel circuit structure of FIG. 3 will be described.

Referring to FIG. 3, each of the plurality of pixels PX may include a pixel circuit having a driving transistor DT, and a light-emitting element EL connected to the pixel circuit.

The pixel circuit may drive the light-emitting element EL by controlling a driving current flowing in the light-emitting element EL. The pixel circuit may include the driving transistor DT, first to seventh transistors T1 to T7, and a capacitor Cst. Each of the transistors DT and T1 to T7 may include a first electrode, a second electrode, and a gate electrode. One of the first electrode and the second electrode may be a source electrode, and the other may be a drain electrode.

Each of the transistors DT and T1 to T7 may be a p-type thin film transistor or an n-type thin film transistor. In the embodiment of FIG. 3, the first transistor T1 and the seventh transistor T7 are the n-type thin film transistors, and the remaining transistors DT and T2 to T6 are the p-type thin film transistors. However, the embodiments of the present specification are not limited thereto, and all or some of the transistors DT and T1 to T7 may be the p-type thin film transistors or the n-type thin film transistors according to the embodiments. In addition, the n-type thin film transistor may be an oxide thin film transistor including an oxide semiconductor layer, and the p-type thin film transistor may be a polycrystalline silicon thin film transistor including a polycrystalline semiconductor layer.

Hereinafter, an example in which the first transistor T1 and the seventh transistor T7 are the n-type oxide thin film transistors, and the remaining transistors DT and T2 to T6 are the p-type thin film transistors will be described. Accordingly, the first transistor T1 and the seventh transistor T7 are turned on by receiving a high voltage, and the remaining transistors DT and T2 to T6 are turned on by receiving a low voltage.

The first transistor T1 forming the pixel circuit may serve as a compensation transistor, a second transistor T2 may serve as a data supply transistor, third and fourth transistors T3 and T4 may serve as light-emitting control transistors, a fifth transistor T5 may serve as a bias transistor, and sixth and seventh transistors T6 and T7 may serve as initialization transistors.

The light-emitting element EL may include an anode electrode and a cathode electrode. The anode electrode of the light-emitting element EL may be connected to a fifth node N5, and the cathode electrode may be connected to the low-potential driving voltage EVSS.

The driving transistor DT may include a first electrode connected to a second node N2, a second electrode connected to a third node N3, and a gate electrode connected to a first node N1. The driving transistor DT may provide a driving current Id to the light-emitting element EL based on a voltage (or a data voltage stored in the capacitor Cst to be described below) of the first node N1.

The first transistor T1 may include a first electrode connected to the first node N1, a second electrode connected to the third node N3, and a gate electrode that receives a first scan signal SC1. The first transistor T1 may be turned on in response to the first scan signal SC1 and diode-connected between the first node N1 and the third node N3 to sample a threshold voltage (Vth) of the driving transistor DT. The first transistor T1 may be a compensation transistor.

The capacitor Cst may be connected or formed between the first node N1 and a fourth node N4. The capacitor Cst may store or maintain the provided high-potential driving voltage EVDD.

The second transistor T2 may include a first electrode connected to a data line DL (or for receiving the data voltage Vdata), a second electrode connected to the second node N2, and a gate electrode that receives a second scan signal SC2. The second transistor T2 may be turned on in response to the second scan signal SC2 and may transmit the data voltage Vdata to the second node N2. The second transistor T2 may be a data supply transistor.

The third transistor T3 and the fourth transistor T4 (or first and second light-emitting control transistors) may be connected between the high-potential driving voltage EVDD and the light-emitting element EL and may form a current flowing path along which the driving current Id generated by the driving transistor DT flows.

The third transistor T3 may include a first electrode connected to the fourth node N4 and for receiving the high-potential driving voltage EVDD, a second electrode connected to the second node N2, and a gate electrode that receives the light-emitting control signal EM.

The fourth transistor T4 may include a first electrode connected to the third node N3, a second electrode connected to the fifth node N5 (or the anode electrode of the light-emitting element EL), and a gate electrode that receives the light-emitting control signal EM.

The third and fourth transistors T3 and T4 are turned on in response to the light-emitting control signal EM, and in this case, the driving current Id may be provided to the light-emitting element EL, and the light-emitting element EL may emit light with luminance corresponding to the driving current Id.

The fifth transistor T5 may include a first electrode that receives the bias voltage Vobs, a second electrode connected to the second node N2, and a gate electrode that receives the third scan signal SC3. The fifth transistor T5 may be a bias transistor.

The sixth transistor T6 may include a first electrode that receives the first initialization voltage Var, a second electrode connected to the fifth node N5, and a gate electrode that receives the third scan signal SC3.

The sixth transistor T6 may be turned on in response to the light-emitting control signal SC3 before the light-emitting element EL emits light (or after the light-emitting element EL emits light) and may initialize the anode electrode (or the pixel electrode) of the light-emitting element EL using the first initialization voltage Var.

The light-emitting element EL may have a parasitic capacitor formed between the anode electrode and the cathode electrode. In addition, while the light-emitting element EL emits light, the parasitic capacitor may be charged so that the anode electrode of the light-emitting element EL may have a specific voltage. In particular, such a phenomenon may be noticeably when the display apparatus is driven in the VRR mode.

Accordingly, the amount of charge accumulated in the light-emitting element EL may be initialized by applying the first initialization voltage Var to the anode electrode of the light-emitting element EL through the sixth transistor T6.

The first initialization voltage Var may be supplied through the anode reset line VAR_L connecting a supply source of the first initialization voltage Var, that is, the power supply unit 500, to the first electrode of the sixth transistor T6. The first initialization voltage Var may also be referred to as an “anode reset voltage.”

In the present specification, the gate electrodes of the fifth and sixth transistors T5 and T6 are formed to commonly receive the third scan signal SC3. However, the present disclosure is not necessarily limited thereto, and the gate electrodes of the fifth and sixth transistors T5 and T6 may be formed to be independently controlled by receiving separate scan signals.

The seventh transistor T7 may include a first electrode that receives the second initialization voltage Vini, a second electrode connected to the first node N1, and a gate electrode that receives the fourth scan signal SC4.

The seventh transistor T7 may be turned on in response to the fourth scan signal SC4 and may initialize the gate electrode of the driving transistor DT using the second initialization voltage Vini. Unnecessary charges may remain in the gate electrode of the driving transistor DT due to the high-potential driving voltage EVDD stored in the capacitor Cst. Accordingly, the amount of the remaining charges may be initialized by applying the second initialization voltage Vini to the gate electrode of the driving transistor DT through the seventh transistor T7. The second initialization voltage Vini may also be referred to as an “gate reset voltage.”

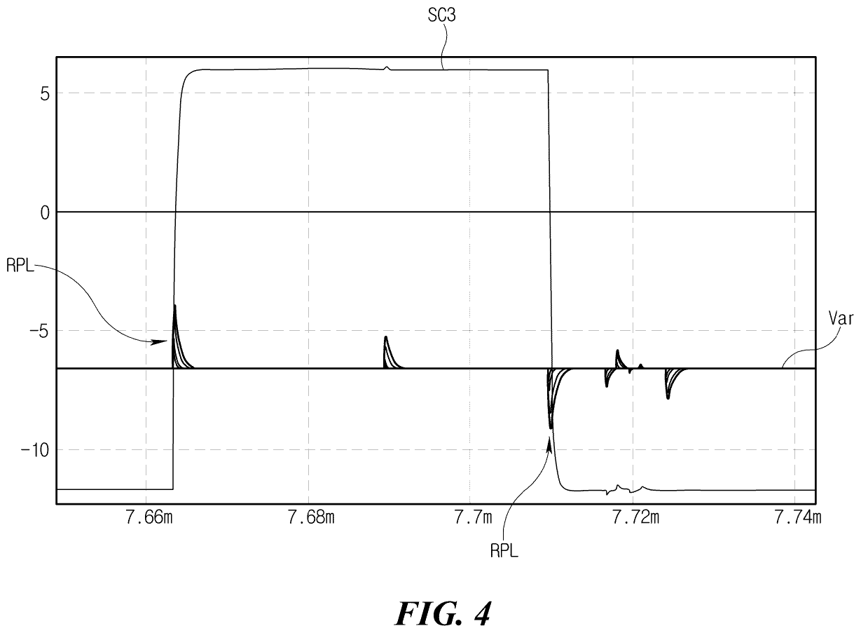

FIG. 4 is a waveform diagram illustrating a ripple phenomenon of an anode reset voltage.

As described above, the display apparatus may be operated as the VRR mode display apparatus. In the VRR mode, a pixel may be driven at a general frequency and then operated by increasing a refresh rate with updated data voltage Vdata at a time point at which high-speed driving is required, or the pixel may be operated by decreasing the refresh rate at a time point at which power consumption is decreased or low-speed driving is required.

The display apparatus may be driven to repeatedly have a combination of a refresh period in which the data voltage Vdata is updated and a hold period in which the data voltage Vdata is not updated in the VRR driving mode. The display apparatus may have a set of the refresh period and the hold period, and the set may be repeated periodically.

In the refresh period, a new data voltage Vdata is charged, and the new data voltage Vdata is applied to the driving transistor DT, while in the hold period, a data voltage Vdata of a previous frame is maintained as it is and used.

In each of the plurality of pixels PX, the voltage that is charged or remains in the pixel circuit may be initialized in the refresh period. Specifically, in each of the plurality of pixels PX, the influence of the data voltage Vdata stored in the previous frame and the high-potential driving voltage EVDD can be removed in the refresh period. Accordingly, in each of the plurality of pixels PX, an image corresponding to the new data voltage Vdata may be displayed in the hold period.

In each of the plurality of pixels PX, the image may be displayed by providing a driving current corresponding to the data voltage Vdata to the light-emitting element EL in the hold period, and a turn-on state of the light-emitting element EL may be maintained.

The refresh period or the hold period may include at least one anode reset period. In particular, to improve flicker that occurs as the hold period is longer during low-speed driving, at least one anode reset period may be set within the hold period so that the node connected to the anode electrode of the light-emitting element EL may be periodically reset to a predetermined voltage, such as the anode initialization voltage Var.

Meanwhile, referring to FIG. 4, as described above, while the display apparatus 10 is driven in the VRR mode, the third scan signal SC3 fluctuates from an on level to an off level or from the off level to the on level to initialize the anode electrode.

In this case, a ripple RPL may occur in the anode reset voltage Var supplied to the anode reset line VAR_L due to the kickback phenomenon. In particular, when the resistance of the anode reset line VAR_L is large, the level of the ripple RPL increases, and image quality abnormality may occur.

As described, voltage ripple in the anode reset line VAR_L can occur during VRR operation, potentially degrading image quality. The following sections describe various embodiments aimed at reducing resistance and stabilizing the anode reset voltage.

For example, a structure capable of minimizing the above fluctuation of the anode reset voltage Var will be described with reference to FIGS. 5 to 15.

FIG. 5 is a plan view illustrating a display panel and a printed circuit board according to one embodiment.

Referring to FIG. 5, the display panel 100 may include a display area DA including a plurality of pixels PX and a non-display area NDA around the display area DA.

The display area DA may include short sides extending in a first direction DR1 and long sides extending in a second direction DR2. The non-display area NDA may surround the display area DA. The non-display area NDA may be located at one side in the first direction DR1, the other side in the first direction DR1, one side in the second direction DR2, and the other side in the second direction DR2 of the display area DA, but the embodiments of the present specification are not limited thereto.

The non-display area NDA located at the other side of the display area DA in the second direction DR2 may extend further from a central portion of the other side in the second direction DR2 toward the other side in the second direction DR2 of the display area DA. A width of the non-display area NDA in the first direction DR1 further extending from the central portion of the other side in the second direction DR2 toward the other side in the second direction DR2 of the display area DA may be smaller than a width of the non-display area NDA in the first direction DR1 adjacent to the other side of the display area DA in the second direction DR2.

The display apparatus 10 may include a main region MR, a sub-region SR, and a bending region BR between the main region MR and the sub-region SR. The display area DA and the non-display area NDA surrounding four surfaces of the display area DA may constitute the main region MR. A portion extending further from the central portion of the other side in the second direction DR2 toward the other side of the second direction DR2 of the display area DA may constitute the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. A touch panel TISP may have substantially the same size as the main region MR, but the embodiments of the present specification are not limited thereto. For example, the main region MR may be a main region or a display area, but is not limited thereto. For example, the sub-region SR may be a sub-region, but is not limited thereto. For example, the bending region BR may be a bending region or a variable region, but is not limited thereto.

As described above, the gate driving unit 300 may be embedded in the display panel 100 by a GIP method. The data driving unit 400 may be disposed in the first pad area PA1.

The display apparatus 10 may further include a printed circuit board FPCB attached to the second pad area PA2. The controller 200 and the power supply unit 500 may be mounted on the printed circuit board FPCB.

A plurality of pads connected to the data driving unit 400 and the printed circuit board FPCB may be disposed in each of the first pad area PA1 and the second pad area PA2. The data driving unit 400 may be formed, for example, in the form of a driving chip (IC), but is not limited thereto. In one embodiment, a case in which the data driving unit 400 is disposed by a chip-on-plastic method that the data driving unit 400 is directly mounted on the display panel 100 has been described.

The printed circuit board FPCB may further include a connector CN and may be electrically connected to a main circuit board, etc., through the connector CN, but the embodiments of the present specification are not limited thereto.

The plurality of pixels PX may be electrically connected to data lines DL1 and DL2, respectively. The data lines DL1 and DL2 may extend in the second direction DR2 and may be spaced apart from each other in the first direction DR1.

The data lines DL1 and DL2 may include a first data line DL1 directly electrically connected to the data driving unit 400 and a second data line DL2 not directly connected to the data driving unit 400.

Hereinafter, the first data line DL1 is defined as a line that is directly connected to the data driving unit 400 and supplies a data voltage to pixels PX, and the second data line DL2 is defined as a line that is not directly connected to the data driving unit 400 but is electrically connected to the data driving unit 400 through a separate line and supplies a data voltage to pixels PX.

The display panel 100 may further include a plurality of vertical connection lines LIA_V, a plurality of horizontal connection lines LIA_H, and a plurality of dummy lines. The dummy line may be a line that is formed along with the vertical connection line LIA_V or the horizontal connection line LIA_H but is not used for transmitting a data voltage.

The plurality of dummy lines may include a plurality of dummy vertical connection lines LIA_V_D and a plurality of dummy horizontal connection lines LIA_H_D. The dummy horizontal connection line LIA_H_D may be referred to as a “first dummy line” or a “horizontal dummy line,” and the dummy vertical connection line LIA_V_D may be referred to as a “second dummy line” or a “vertical dummy line.”

At least parts of the vertical connection line LIA_V, the horizontal connection line LIA_H, the dummy vertical connection line LIA_V_D, and the dummy horizontal connection line LIA_H_D may be disposed in an active area. The active area may be substantially the same as the display area DA.

The vertical connection line LIA_V may extend in the second direction DR2. The vertical connection line LIA_V may be directly electrically connected to the data driving unit 400. The vertical connection line LIA_V may be electrically connected to the horizontal connection line LIA_H through a first through hole TH1. The vertical connection line LIA_V may be electrically separated from the dummy vertical connection line LIA_V_D.

The horizontal connection line LIA_H may electrically connect the vertical connection line LIA_V connected to the data driving unit 400 to the second data line DL2. The horizontal connection line LIA_H may extend in the first direction DR1. The horizontal connection line LIA_H may be electrically connected to the second data line DL2 through a second through hole TH2. The horizontal connection line LIA_H may be electrically separated from the dummy horizontal connection line LIA_H_D.

In some embodiments, some of the plurality of vertical connection lines LIA_V may not be directly connected to the data driving unit 400, and the second data line DL2 may be connected to the horizontal connection line LIA_H via the vertical connection line LIA_V that is not directly connected to the data driving unit 400.

The vertical connection line LIA_V and the horizontal connection line LIA_H may be located on different layers. The data lines DL1 and DL2 and the vertical connection line LIA_V may be located on the same layer, and the data lines DL1 and DL2 may be located on a different layer from the horizontal connection line LIA_H. The vertical connection line LIA_V and the dummy vertical connection line LIA_V_D may be located on the same layer. The horizontal connection line LIA_H and the dummy horizontal connection line LIA_V_D may be located on the same layer.

The horizontal connection line LIA_H and the dummy horizontal connection line LIA_H_D may be located on the same extension line extending in the first direction DR1. The plurality of horizontal connection lines LIA_H and the plurality of dummy horizontal connection lines LIA_H_D may be formed on the same layer and formed by cutting the plurality of conductive lines extending in the first direction DR1.

The vertical connection line LIA_V and the dummy vertical connection line LIA_V_D may be located on the same extension line extending in the second direction DR2. The plurality of vertical connection lines LIA_V and the plurality of dummy vertical connection lines LIA_V_D may be formed on the same layer and formed by cutting the plurality of conductive lines extending in the second direction DR2.

The vertical connection line LIA_V and the dummy vertical connection line LIA_V_D may be located on the same layer as at least one of the first data line DL1 and the second data line DL2. The vertical connection line LIA_V and the dummy vertical connection line LIA_V_D may be located simultaneously with at least one of the first data line DL1 and the second data line DL2. In one embodiment, the vertical connection line LIA_V, the dummy vertical connection line LIA_V_D, the first data line DL1, and the second data line DL2 may be located on the same layer, but are not limited thereto.

To connect the second data line DL2 to the data driving unit 400, only the plurality of vertical connection lines LIA_V and the plurality of horizontal connection lines LIA_H may be formed on a part of the display panel 100. However, when a pattern is formed only in a part of the display panel 100, the part and other parts in which the pattern is not formed may be distinguished and visible.

Accordingly, a plurality of lines extending in the first direction DR1 may be formed on the entirety of the display panel 100, and some of the plurality of lines may be appropriately cut to form the plurality of horizontal connection lines LIA_H and the plurality of dummy horizontal connection lines LIA_H_D. Likewise, a plurality of lines extending in the second direction DR2 may be formed on the entirety of the display panel 100, and some of the plurality of lines may be appropriately cut to form the plurality of vertical connection lines LIA_V and the plurality of dummy vertical connection lines LIA_V_D.

On the display panel 100, a contact area CON_A in which the second data line DL2 comes into contact with the horizontal connection line LIA_H and/or the vertical connection line LIA_V may be defined. The contact area CON_A may be located adjacent to a lower edge of the display panel 100 and/or the display area DA in a plan view. In one embodiment, the contact area CON_A may have a triangular shape in a plan view, but is not limited thereto.

In one embodiment, the second data line DL2 and the horizontal connection line LIA_H may be contacted in the contact area CON_A, and the horizontal connection line LIA_H may come into contact with the vertical connection line LIA_V. That is, the first through hole TH1 and the second through hole TH2 may be located only in the contact area CON_A. In some embodiments, the second data line DL2 may come into contact with the vertical connection line LIA_V in the contact area CON_A.

The first data line DL1 may be located outside the contact area CON_A, or a part thereof may pass the contact area CON_A. The horizontal connection line LIA_H may be located in the contact area CON_A. The dummy horizontal connection line LIA_H_D may be located outside the contact area CON_A.

The vertical connection line LIA_V may be located outside the contact area CON_A. All of the dummy vertical connection lines LIA_V_D may be located outside the contact area CON_A, or some may be located in the contact area CON_A and the others may be located outside the contact area CON_A.

The second data line DL2 may be located at portions adjacent to left and right edges of the display panel 100. Since the second data line DL2 is connected to the data driving unit via the connection lines LIA_V and LIA_H disposed in the display area DA, it is possible to reduce a space for a fan-out line arrangement for direct connection between the second data line DL2 and the data driving unit 400, thereby reducing a bezel area of a lower end of the display panel 100.

The display panel 100 may further include the anode reset line VAR_L through which the anode reset voltage Var for resetting the anode electrode is supplied to each pixel PX.

The anode reset line VAR_L may include a plurality of horizontal anode reset lines VAR_HL and a fan-out anode reset line VAR_FL. The horizontal anode reset line VAR_HL and the fan-out anode reset line VAR_FL may be referred to as a “first anode reset line” and a “second anode reset line,” respectively.

The horizontal anode reset line VAR_HL may be mainly disposed in the display area DA. One side of the horizontal anode reset line VAR_HL may be connected to the fan-out anode reset line VAR_FL located at one side of the display panel 100, and the other side of the horizontal anode reset line VAR_HL may be connected to the fan-out anode reset line VAR_FL located at the other side of the display panel 100.

The fan-out anode reset line VAR_FL may be disposed in the non-display area NDA. The fan-out anode reset line VAR_FL may be disposed to surround the display area DA and the horizontal anode reset line VAR_HL. The fan-out anode reset line VAR_FL may extend from the printed circuit board FPCB in the second direction DR2 and pass the sub-region SR and the bending region BR. The fan-out anode reset line VAR_FL may be, for example, bent in the first direction DR1 in the non-display area NDA and then may re-extend in the second direction DR2.

The fan-out anode reset line VAR_FL may be connected to the power supply unit 500 to receive the anode reset voltage Var from the power supply unit 500 and transmit the anode reset voltage Var to the horizontal anode reset line VAR_HL.

The anode reset line VAR_L may be electrically connected to the dummy vertical connection line LIA_V_D. The horizontal anode reset line VAR_HL may be connected to the dummy horizontal connection line LIA_H_D through a first contact hole CH1. The dummy horizontal connection line LIA_H_D may be connected to the dummy vertical connection line LIA_V_D through a second contact hole CH2. That is, the horizontal anode reset line VAR_HL may be connected to the dummy vertical connection line LIA_V_D via the dummy horizontal connection line LIA_H_D.

The dummy vertical connection line LIA_V_D may be connected to the power supply unit 500 through a line (not illustrated), and the anode reset voltage Var may be supplied to the dummy vertical connection line LIA_V_D. Accordingly, the anode reset voltage Var may be uniformly supplied across the display panel 100, and the fluctuation of the anode reset voltage Var can be reduced. In some embodiments, the dummy vertical connection line LIA_V_D may not be electrically connected to lines or components other than the dummy horizontal connection line LIA_H_D.

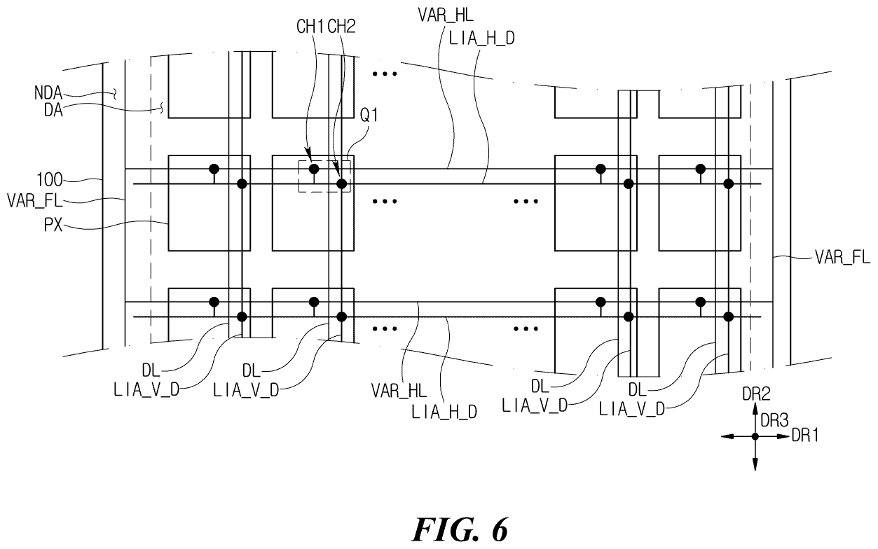

FIG. 6 is an enlarged plan view of a part of the display panel according to one embodiment.

Referring to FIG. 6, a plurality of pixels PX are disposed to constitute a plurality of rows extending in the first direction DR1 and a plurality of columns in the second direction DR2.

The horizontal anode reset line VAR_HL and the dummy horizontal connection line LIA_H_D may be disposed in each pixel PX row, and the data line DL and the dummy vertical connection line LIA_V_D may be disposed in each pixel PX column. The data line DL may be the first data line DL1 or the second data line DL2.

For convenience of description, FIG. 6 illustrates the horizontal anode reset line VAR_HL spaced apart from the horizontal connection line LIA_H, but at least a part of the horizontal anode reset line VAR_HL may overlap the horizontal connection line LIA_H in a thickness direction (a third direction).

The horizontal anode reset line VAR_HL disposed in the pixel PX row may be electrically connected to the plurality of dummy vertical connection lines LIA_V_D passing the pixel PX row via the dummy horizontal connection line LIA_H_D disposed in the pixel PX row.

In one embodiment, the plurality of dummy vertical connection lines LIA_V_D may be electrically connected to the horizontal anode reset line VAR_HL regardless of the location of the dummy vertical connection line LIA_V_D in the display panel 100. For example, both the dummy vertical connection lines LIA_V_D located at both edge portions of the display panel 100 and the dummy vertical connection lines LIA_V_D located at the central portion of the display panel 100 may be electrically connected to the horizontal anode reset line VAR_HL.

As another example, the horizontal anode reset line VAR_HL and the dummy vertical connection line LIA_V_D may be connected through the dummy horizontal connection line LIA_H_D in all pixels PX constituting one pixel PX row.

In the same manner, the horizontal anode reset line VAR_HL and the dummy vertical connection line LIA_V_D may be connected through the dummy horizontal connection line LIA_H_D in the plurality of pixel PX rows across the display panel 100.

In some embodiments, the anode reset line VAR_L and the dummy vertical connection line LIA_V_D may be electrically connected only in some of the pixels PX constituting one pixel PX row. For example, in the pixel PX row passing the contact area CON_A, the anode reset line VAR_L and the dummy vertical connection line LIA_V_D may be electrically connected only in pixels PX located outside the contact area CON_A through the dummy horizontal connection line LIA_H_D. In this case, the anode reset line VAR_L and the dummy vertical connection line LIA_V_D may be directly connected in the contact area CON_A.

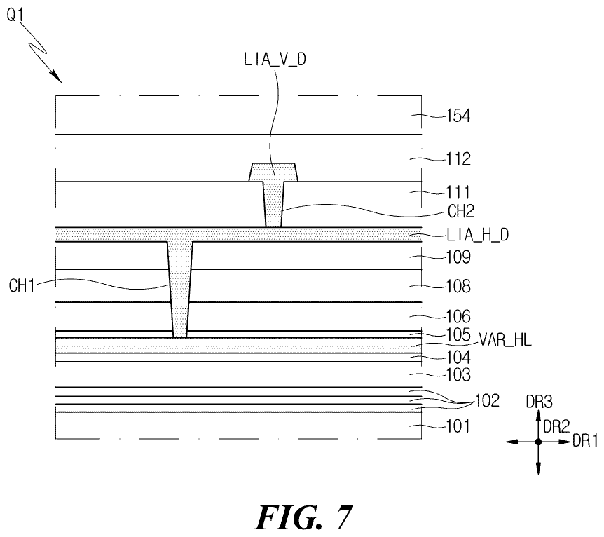

FIG. 7 is a cross-sectional view of portion Q1 of FIG. 6 taken in a first direction.

Referring to FIG. 7, the anode reset line VAR_L may be formed on a different layer from the dummy horizontal connection line LIA_H_D and the dummy vertical connection line LIA_V_D. The horizontal anode reset line VAR_HL and the fan-out anode reset line VAR_FL may be formed on the same layer. However, the embodiments of the present specification are not limited thereto, and the horizontal anode reset line VAR_HL and the fan-out anode reset line VAR_FL may be formed on different layers.

The horizontal anode reset line VAR_HL may be formed on the second insulating layer 104. The third insulating layer 105 may be formed on the horizontal anode reset line VAR_HL. The horizontal anode reset line VAR_HL may be located between the second insulating layer 104 and the third insulating layer 105.

The horizontal anode reset line VAR_HL may be formed on the same layer as at least one of the first gate electrode 122 and the first storage electrode 141. The horizontal anode reset line VAR_HL may be formed concurrently (or in some embodiments, simultaneously) with at least one of the first gate electrode 122 and the first storage electrode 141.

The dummy horizontal connection line LIA_H_D may be formed on the sixth insulating layer 109. The first protective layer 111 may be formed on the dummy horizontal connection line LIA_H_D. The dummy horizontal connection line LIA_H_D may be located between the sixth insulating layer 109 and the first protective layer 111. As described above, the horizontal connection line LIA_H may be formed on the same layer as the dummy horizontal connection line LIA_H_D.

The dummy horizontal connection line LIA_H_D may be formed on the same layer as at least one of the first source electrode 121, the first drain electrode 124, the third storage electrode 143, the second source electrode 131, and the second drain electrode 134. The dummy horizontal connection line LIA_H_D may be formed concurrently (or in some embodiments, simultaneously) with at least one of the first source electrode 121, the first drain electrode 124, the third storage electrode 143, the second source electrode 131, and the second drain electrode 134.

The dummy vertical connection line LIA_V_D may be formed on the first protective layer 111. The second protective layer 112 may be formed on the dummy vertical connection line LIA_V_D. The dummy vertical connection line LIA_V_D may be located between the first protective layer 111 and the second protective layer 112. As described above, the vertical connection line LIA_V may be formed on the same layer as the dummy vertical connection line LIA_V_D.

The first contact hole CH1 and the second contact hole CH2 may be formed to pass through at least one layer.

The first contact hole CH1 may pass through a plurality of insulating layers to connect the horizontal anode reset line VAR_HL to the dummy horizontal connection line LIA_H_D. The first contact hole CH1 may pass through the third insulating layer 105, the fourth insulating layer 106, the fifth insulating layer 108, and the sixth insulating layer 109.

The second contact hole CH2 may pass through the first protective layer 111 to connect the dummy horizontal connection line LIA_H_D to the dummy vertical connection line LIA_V_D.

In FIG. 7, the first contact hole CH1 and the second contact hole CH2 do not overlap each other in the thickness direction, but are not limited thereto. The first contact hole CH1 and the second contact hole CH2 may also be formed to overlap each other in the thickness direction.

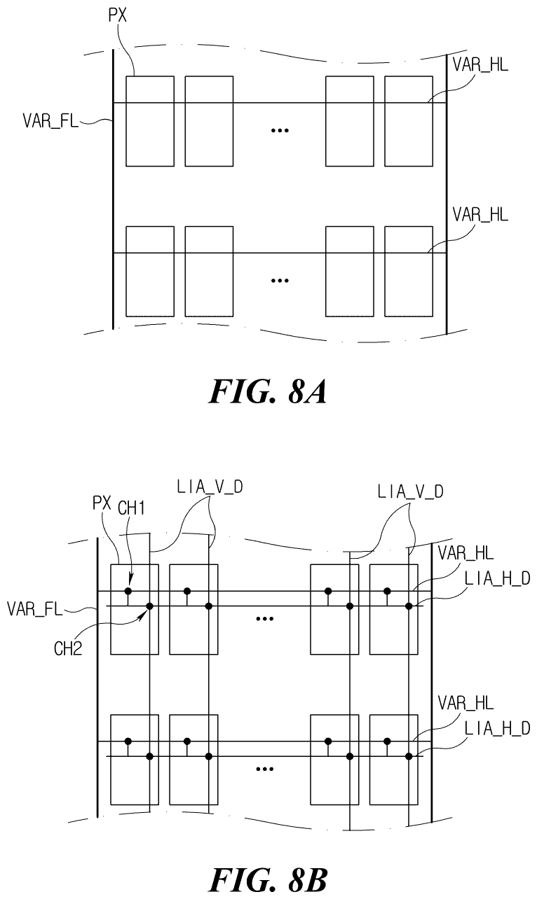

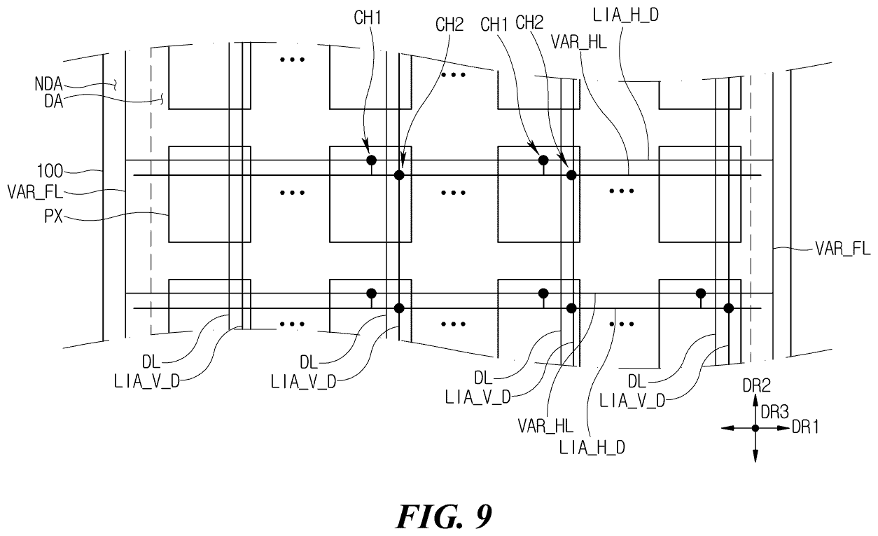

FIGS. 8A and 8B are views illustrating comparison between the display apparatus according to one embodiment and a display apparatus according to a comparative example.

FIG. 8A is a schematic plan view illustrating a part of the display panel 100 of the display apparatus 10 according to a comparative example. FIG. 8B is a schematic plan view illustrating a part of the display panel 100 of the display apparatus 10 according to one embodiment.

As described above, to minimize image quality abnormality, particularly, image quality abnormality when the display apparatus is driven in the VRR mode, the anode reset voltage Var may be applied to the anode electrode. In this case, to prevent or minimize the fluctuation of the anode reset voltage due to the driving of the display panel 100, such as the switching of the initialization transistor T6, the resistance of the anode reset line VAR_L needs to be minimized.

Referring to FIG. 8A, the display apparatus 10 according to the comparative example does not have a separate line connected to the horizontal anode reset line VAR_HL in order to reduce the resistance of the horizontal anode reset line VAR_HL.

On the other hand, when the pixel circuit includes an oxide semiconductor, the element stability is reduced and thus a shield structure (e.g., the first light-shielding layer 126 of FIG. 2) is required, and as a result, it is difficult to use a relatively wide low-resistance line as the anode reset line VAR_L.

Accordingly, the horizontal anode reset line VAR_HL of the display apparatus 10 according to the comparative example has a relatively high resistance value, and the ripple RPL as illustrated in FIG. 4 may largely occur when the initialization transistor T6 is switched. According to various embodiments of the present disclosure, an electrical connection between the anode reset line and the dummy line, in operation, reduces resistance of the anode reset line and reduces ripple in the anode reset voltage during switching of the initialization transistor. This will be explained in more detail below.

Referring to FIG. 8B, in the display apparatus 10 according to one embodiment, the horizontal anode reset line VAR_HL may be electrically connected to the dummy vertical connection line LIA_V_D via the dummy horizontal connection line LIA_H_D. That is, in the display apparatus 10 according to one embodiment, the horizontal anode reset line VAR_HL, the dummy horizontal connection line LIA_H_D, and the dummy vertical connection line LIA_V_D may be connected to form a mesh structure.

As described above, the dummy horizontal connection line LIA_H_D and the dummy vertical connection line LIA_V_D are formed along with the horizontal connection line LIA_H or the vertical connection line LIA_V, but are not used for transmitting the data voltage. The display apparatus 10 according to one embodiment uses such a dummy line to reduce the resistance of the anode reset line VAR_L.

Accordingly, it is possible to minimize the line resistance of the anode reset voltage Var, thereby preventing the fluctuation of the anode reset voltage Var, or even when the fluctuation of the anode reset voltage Var occur, the anode reset voltage Var can be quickly recovered to the originally intended level of the anode reset voltage Var at the corresponding time point. In addition, it is possible to increase the degree of freedom related to the layout design for the arrangement of other components and omit a process for forming a separate low-resistance line, for example, reduce the number of masks.

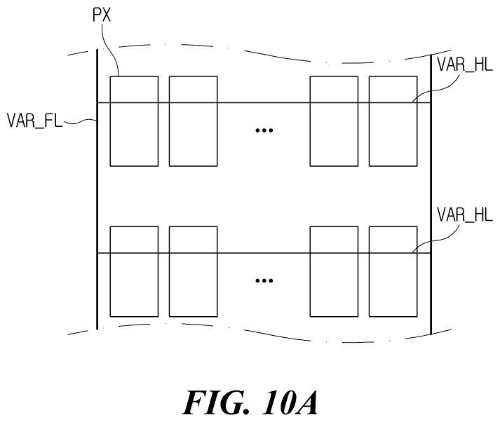

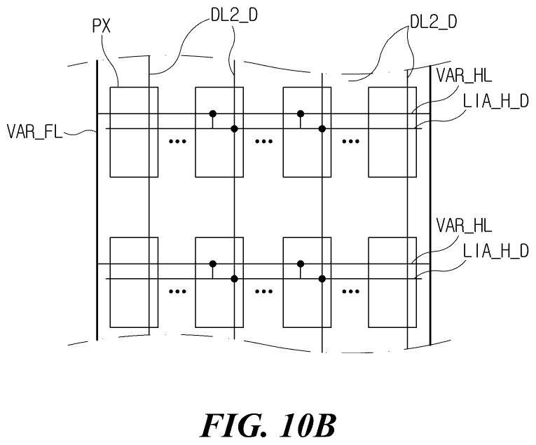

FIG. 9 is an enlarged plan view of a part of a display panel of a display apparatus according to another embodiment. FIGS. 10A and 10B illustrate comparison between the display apparatus according to another embodiment and the display apparatus according to the comparative example.

FIG. 10A is a schematic plan view illustrating a part of the display panel 100 of the display apparatus 10 according to the comparative example. FIG. 10B is a schematic plan view illustrating a part of the display panel 100 of the display apparatus 10 according to one embodiment.

Since the embodiments of FIGS. 9 and 10B are substantially the same as the embodiments of FIGS. 1 to 8 except for the connection configuration of the anode reset line VAR_L, differences therebetween will be mainly described below.

Referring to FIG. 9, some of the plurality of dummy vertical connection lines LIA_V_D may not be electrically connected to the horizontal anode reset line VAR_HL. Among the plurality of dummy vertical connection lines LIA_V_D, only the dummy vertical connection lines LIA_V_D located at the central portion of the display panel 100 may be electrically connected to the horizontal anode reset line VAR_HL. Among the plurality of dummy vertical connection lines LIA_V_D, only the dummy vertical connection lines LIA_V_D located at the both edge portions of the display panel 100 may not be electrically connected to the horizontal anode reset line VAR_HL. Accordingly, the first contact hole CH1 and the second contact hole CH2 may be formed at only the central portion of the display panel 100.

For example, in at least one of the plurality of pixel PX columns, which is disposed at both edge portions of the display panel 100, the horizontal anode reset line VAR_HL may not be electrically connected to the dummy vertical connection line LIA_V_D. The at least one pixel PX column disposed at both edge portions of the display panel 100 may include a pixel PX column disposed at a leftmost or rightmost side of the display panel 100 and at least one pixel PX column adjacent thereto. On the other hand, in at least one of the plurality of pixel PX columns, which is disposed at the central portion of the display panel 100, the horizontal anode reset line VAR_HL may be electrically connected to the dummy vertical connection line LIA_V_D.

Referring to FIG. 10A, the low-resistance fan-out anode reset line VAR_FL may be disposed at the edge of the display panel 100, that is, the non-display area NDA. Accordingly, the line resistance of the anode reset line VAR_L at the edge portion of the display panel 100 is relatively low. On the other hand, the line resistance of the horizontal anode reset line VAR_HL gradually increases toward the central portion of the display panel 100. As illustrated in FIG. 8B, this also applies to a case in which the anode reset line VAR_L is connected to the dummy vertical connection line LIA_V_D.

Meanwhile, referring to FIGS. 9 and 10B, since only the dummy vertical connection lines LIA_V_D located at the central portion of the display panel 100 are selectively connected to the horizontal anode reset line VAR_HL, it is possible to improve the uniformity of the line resistance of the anode reset line VAR_L across the left and right sides of the display panel 100. The number of dummy vertical connection lines LIA_V_D not connected to the horizontal anode reset line VAR_HL may be appropriately adjusted so that the line resistance of the anode reset line VAR_L becomes uniform across the left and right sides of the display panel 100.

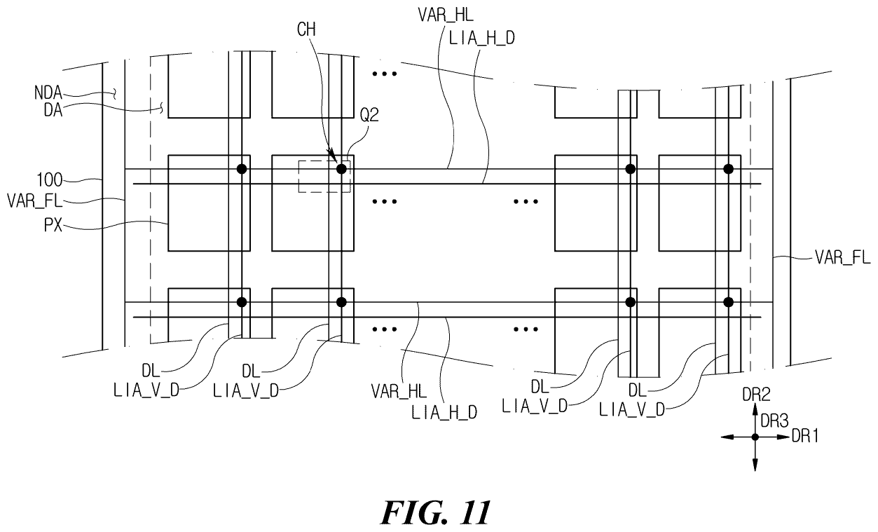

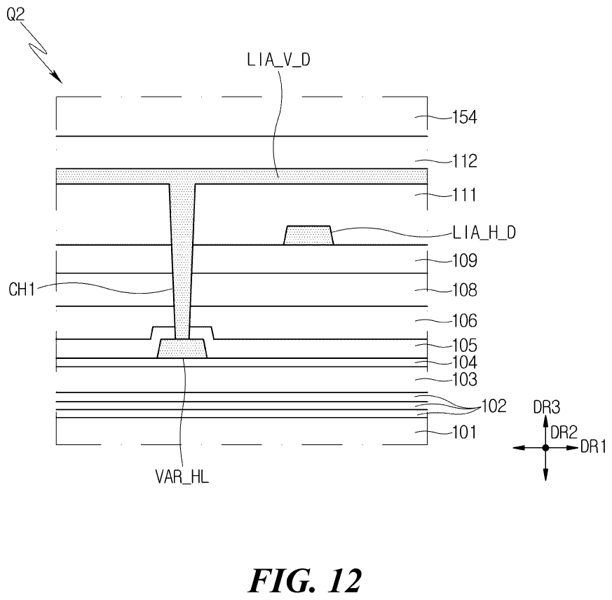

FIG. 11 is an enlarged plan view of a part of a display panel of a display apparatus according to still another embodiment. FIG. 12 is a cross-sectional view of portion Q2 of FIG. 11 taken in a second direction.

Since the embodiments of FIGS. 11 and 12 are substantially the same as the embodiments of FIGS. 1 to 10B except for the connection relationship between the horizontal anode reset line VAR_HL and the dummy vertical connection line LIA_V_D, differences therebetween will be mainly described below.

Referring to FIGS. 11 and 12, the horizontal anode reset line VAR_HL may be directly connected to the dummy vertical connection line LIA_V_D through a contact hole. That is, unlike the embodiments of FIGS. 1 to 8, the horizontal anode reset line VAR_HL may be directly connected to the dummy vertical connection line LIA_V_D without passing the dummy horizontal connection line LIA_H_D.

Referring to FIG. 12, a contact hole CH1 may be formed to pass through the third insulating layer 105, the fourth insulating layer 106, the fifth insulating layer 108, the sixth insulating layer 109, and the first protective layer 111. At least some of the horizontal anode reset lines VAR_HL may be disposed so as not to overlap the contact hole CH in the thickness direction. At least some of the horizontal anode reset lines VAR_HL may be disposed to bypass the contact hole CH. The others of the horizontal anode reset lines VAR_HL may be disposed to overlap the horizontal anode reset line VAR_HL in the thickness direction, but are not limited thereto.

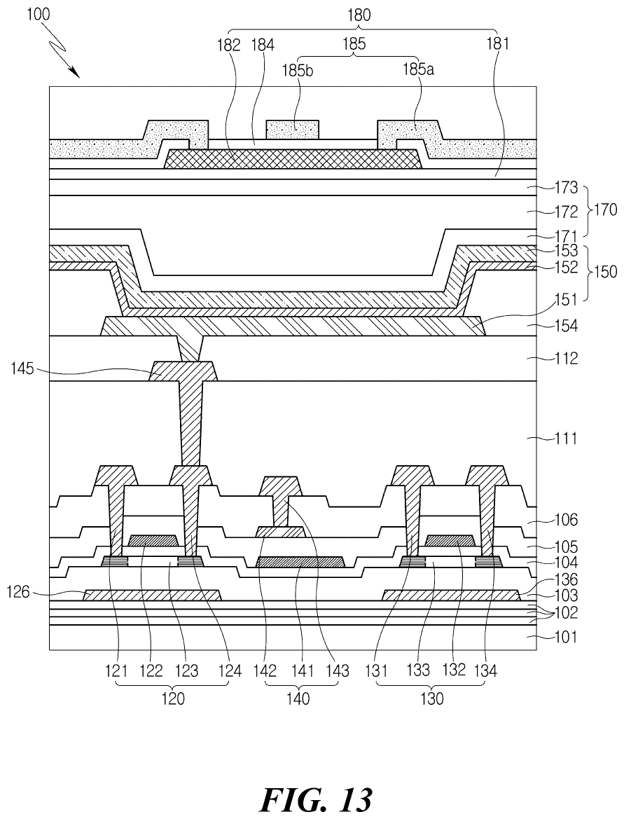

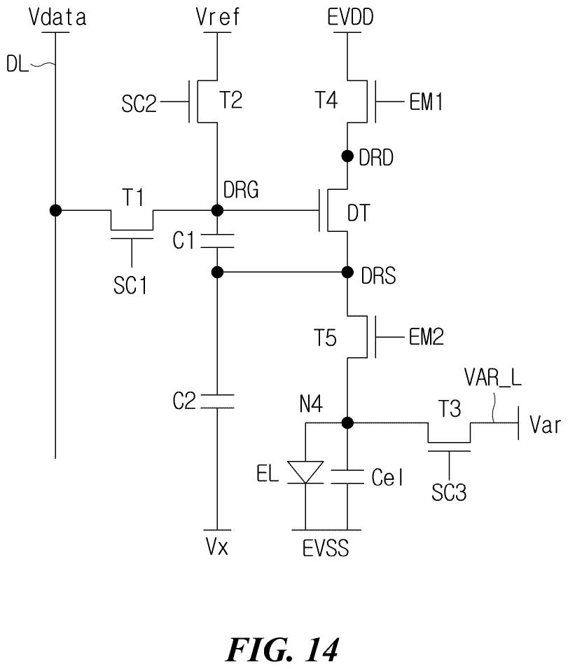

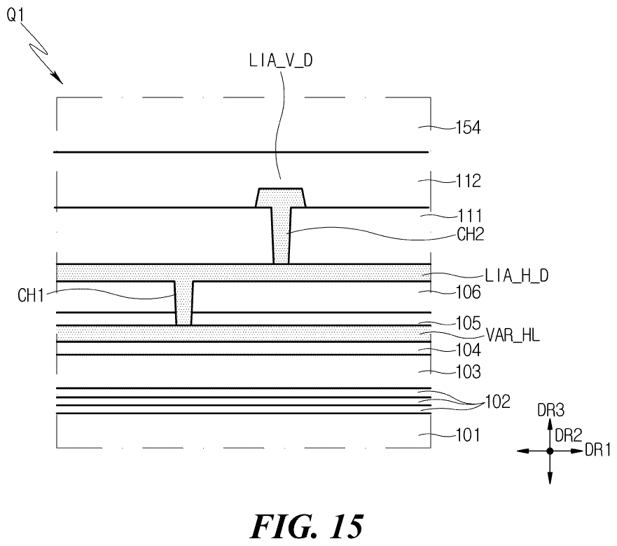

FIG. 13 is a cross-sectional view illustrating a stacked form of the display apparatus according to still another embodiment. FIG. 14 is a view illustrating a pixel circuit in the display apparatus according to still another embodiment. FIG. 15 is a cross-sectional view illustrating a connecting portion of an anode reset line and a dummy vertical connection line of the display apparatus according to still another embodiment.

Since the embodiments of FIGS. 13 to 15 are substantially the same as the embodiments of FIGS. 1 to 8 except for the pixel circuit and panel stacking structure, differences therebetween will be mainly described below.

Referring to FIG. 13, the present embodiment differs from the panel stacking structure illustrated in FIG. 2 in that both the first thin film transistor 120 and the second thin film transistor 130 are oxide transistors and the fifth insulating layer 108 and the sixth insulating layer 109 are omitted.

The second light-shielding layer 136 may be formed on the same layer as the first light-shielding layer 126. The second light-shielding layer 136 may be formed on the buffer layer 102, and the first insulating layer 103 may be formed on the second light-shielding layer 136.

The second semiconductor layer 133 may be formed on the same layer as the first semiconductor layer 123. The second semiconductor layer 133 may be formed on the first insulating layer 103, and the second insulating layer 104 may be formed on the second semiconductor layer 133.

The second gate electrode 132 may be formed on the same layer as the first gate electrode 122. The second gate electrode 132 may be formed on the second insulating layer 104, and the third insulating layer 105 may be formed on the second gate electrode 132.

The second source electrode 131 and the second drain electrode 134 may be formed on the same layer as the first source electrode 121 and the first drain electrode 124. The second source electrode 131 and the second drain electrode 134 may be formed on the fourth insulating layer 106, and the first protective layer 111 may be formed on the second source electrode 131 and the second drain electrode 134. The second source electrode 131 and the second drain electrode 134 may be electrically connected to the second semiconductor layer 133 through contact holes.

Referring to FIG. 14, the pixel circuit may include the light-emitting element EL, the driving transistor DT that supplies a current to the light-emitting element EL, the first to fifth transistors T1 to T5, a first capacitor C1, and a second capacitor C2. In the pixel PX circuit, the driving transistor DT and the first to fifth transistors T1 to T5 may be implemented as n-channel oxide TFTs.

The first transistor T1 may serve as a data supply transistor, the second transistor T2 may server as a reference voltage supply transistor, the third transistor T3 may serve as an initialization transistor, and the fourth and fifth transistors T4 and T5 may serve as light-emitting control transistors.

The gate signal may include the first scan signal SC1, the second scan signal SC2, the third scan signal SC3, a first EM signal EM1, and a second EM signal EM2. To drive the pixel PX circuit illustrated in FIG. 14, the gate driving unit 300 may include a first shift register for sequentially outputting the first scan pulse, a second shift register for sequentially outputting the second scan pulse, a third shift register for sequentially outputting the third scan pulse, a fourth shift register for sequentially outputting the first EM pulse EM1, and a fifth shift register for sequentially outputting the second EM pulse EM2.

The constant voltage, such as the pixel PX driving voltage EVDD, the low-potential power voltage EVSS, the reference voltage Vref, the initialization voltage Vini, etc., may be applied to the pixel PX circuit.

Each of the first to fifth transistors T1 to T5 may be turned on when the gate-on voltages VGL and VEL are applied to a gate electrode, while turned off when the gate-off voltages VGH and VEH are applied to the gate electrode. The driving transistor DT may be turned on when the gate-source voltage Vgs is higher than the threshold voltage (Vth) to generate a current according to the gate-source voltage Vgs so that the light-emitting element EL may be driven.

The anode electrode of the light-emitting element EL may be connected to a fourth node N4, and the cathode electrode thereof may be connected to a VSS node to which the low-potential driving voltage EVSS is applied. The VSS node may be connected to the VSS line. The light-emitting element EL may include a capacitor Cel formed between the anode electrode and the cathode electrode.

The driving transistor DT may include the gate electrode connected to a second node DRG, the first electrode connected to a first node DRD, and the second electrode connected to a third node DRS. Accordingly, the voltage applied to each electrode of the driving transistor DT may be the same as voltages of the first to third nodes DRD, DRG, and DRS.

The first capacitor C1 may be connected between the second node DRG and the third node DRS. The first capacitor C1 may store the gate-source voltage Vgs of the driving transistor DT. The second capacitor C2 may be connected between the fourth node n4 and a Vx node. A constant voltage, such as a constant voltage of one of the pixel driving voltage EVDD, the low-potential power voltage EVSS, the reference voltage Vref, and the initialization voltage Vini, may be applied to the Vx node. The Vx node may be connected to the VDD line to which a relatively stable constant voltage, such as the pixel driving voltage EVDD, is applied.

The first transistor T1 may include a gate electrode connected to a first gate line to which the first scan pulse SC1 is applied, a first electrode connected to the data line DL to which the data voltage Vdata is applied, and a second electrode connected to the first node DRD.

The second transistor T2 may include a gate electrode connected to the second gate line to which the second scan signal SC2 is applied, a first electrode connected to the REF line to which the reference voltage Vref is applied, and a second electrode connected to the second node DRG.

When the data voltage Vdata and the reference voltage Vref are applied to the pixel PX circuit through the data line DL, the number of transitions applied to the data line DL increases, that is, a frequency increases, and the power consumption of the display apparatus increases. In contrast, in the present disclosure, since the data line DL to which the data voltage Vdata is applied and the REF line to which the reference voltage Vref is applied are separated, a frequency of the voltage applied to the data line DL can be lowered, thereby reducing power consumption.

The third transistor T3 may include a gate electrode connected to a third gate line to which the third scan signal SC3 is applied, a first electrode connected to the third node DRS, and a second electrode connected to the anode reset line VAR_L to which the anode reset voltage Var is applied.

When the third transistor T3 is turned on, the anode electrode (or the pixel electrode) of the light-emitting element EL connected to the fourth node N4 may be initialized with the anode reset voltage Var.

The fourth transistor T4 may include a gate electrode connected to a fourth gate line to which the first EM pulse EM1 is applied, a first electrode connected to the VDD line, and a second electrode connected to the first node DRD.

The fifth switch transistor T5 may include a gate electrode connected to a fifth gate line to which the second EM pulse EM2 is applied, a first electrode connected to the third node DRS, and a second electrode connected to the fourth node N4.

As described above, the display apparatus 10 may be driven in the VRR mode, and in this case, by periodically resetting the node in which the anode electrode of the light-emitting element EL is connected to the anode reset voltage Var during the hold period within a frame by the anode reset period, it is possible to improve flicker that occurs as the hold period is longer during low-speed driving. Accordingly, in various embodiments, the anode reset line is configured to receive the anode reset voltage during a hold period of a Variable Refresh Rate (VRR) driving mode.

Meanwhile, when the driving transistor DT and the first to fifth transistors T1 to T5 are all oxide transistors, a shield structure (e.g., the light-shielding layers 126 and 136) is required to protect the oxide transistor that is vulnerable to external environments, such as light, oxygen, hydrogen, moisture, etc. In this case, it is difficult to use a wide low-resistance line in the layout design. Accordingly, by connecting an unused dummy line to the anode reset line VAR_L, it is possible to reduce the line resistance of the anode reset line VAR_L, simplify the process, and secure the degree of freedom related to the design.

Referring to FIG. 15, the horizontal anode reset line VAR_HL may be formed on the second insulating layer 104. The third insulating layer 105 may be formed on the horizontal anode reset line VAR_HL. The horizontal anode reset line VAR_HL may be located between the second insulating layer 104 and the third insulating layer 105.

The horizontal anode reset line VAR_HL may be formed on the same layer as at least one of the first gate electrode 122, the second gate electrode 132, and the storage electrode. The horizontal anode reset line VAR_HL may be formed concurrently (or in some embodiments, simultaneously) with at least one of the first gate electrode 122, the second gate electrode 132, and the storage electrode.

The dummy horizontal connection line LIA_H_D may be formed on the fourth insulating layer 106. The first protective layer 111 may be formed on the dummy horizontal connection line LIA_H_D. The dummy horizontal connection line LIA_H_D may be located between the fourth insulating layer 106 and the first protective layer 111. The horizontal connection line LIA_H may be formed on the same layer as the dummy horizontal connection line LIA_H_D.

The dummy horizontal connection line LIA_H_D may be formed on the same layer as at least one of the first source electrode 121, the first drain electrode 124, the third storage electrode 143, the second source electrode 131, and the second drain electrode 134. The dummy horizontal connection line LIA_H_D may be formed concurrently (or in some embodiments, simultaneously) with at least one of the first source electrode 121, the first drain electrode 124, the third storage electrode 143, the second source electrode 131, and the second drain electrode 134.

The dummy vertical connection line LIA_V_D may be formed on the first protective layer 111. The second protective layer 112 may be formed on the dummy vertical connection line LIA_V_D. The dummy vertical connection line LIA_V_D may be located between the first protective layer 111 and the second protective layer 112. The vertical connection line LIA_V may be formed on the same layer as the dummy vertical connection line LIA_V_D.

The first contact hole CH1 and the second contact hole CH2 may be formed to pass through at least one layer.

The first contact hole CH1 may pass through a plurality of insulating layers to connect the horizontal anode reset line VAR_HL to the dummy horizontal connection line LIA_H_D. The first contact hole CH1 may pass through the third insulating layer 105 and the fourth insulating layer 106. The second contact hole CH2 may pass through the first protective layer 111 to connect the dummy horizontal connection line LIA_H_D to the dummy vertical connection line LIA_V_D.

Since the remaining descriptions have been made above in FIGS. 1 to 8, the detailed description thereof will be omitted below.

The various embodiments of the display apparatus described herein lie in their use of existing dummy lines—typically unused structures within the display panel—to reduce the resistance of the anode reset line, which is responsible for resetting the anode electrode in each pixel. By electrically connecting the anode reset line to both horizontal and vertical dummy lines, the system forms a mesh-like structure that distributes the reset voltage more uniformly across the panel. This significantly reduces or minimizes voltage ripple and image quality issues, especially under variable refresh rate (VRR) operation, where stable voltage delivery is critical.

This design not only enhances signal stability and display performance but also eliminates the need for additional low-resistance lines or manufacturing steps, thereby simplifying fabrication and reducing cost. Additionally, it allows more compact routing of data lines within the display area, which supports a narrower bezel and offers greater flexibility in layout design.

The display apparatus 10 according to various embodiments of the present specification may be described as follows.

A display apparatus including a display area that displays an image, and a non-display area located around the display area according to various embodiments of the present specification includes a pixel disposed in the display area and including an anode electrode, an anode reset line that resets the anode electrode, and the dummy line, in which the anode reset line may be electrically connected to the dummy line.

According to the display apparatus according to various embodiments of the present specification, the pixel may further include a light-emitting element including the anode electrode, an organic layer, and a cathode electrode, and an initialization transistor connecting the anode electrode to the anode reset line.

According to the display apparatus according to various embodiments of the present specification, the pixel may further include a driving transistor connected to the anode electrode, and a data supply transistor that supplies a data voltage to the driving transistor.

According to the display apparatus according to various embodiments of the present specification, the dummy line may include a first dummy line extending in a first direction, and a second dummy line extending in a second direction intersecting the first direction, and the anode reset line may be electrically connected to the second dummy line.

According to the display apparatus according to various embodiments of the present specification, the anode reset line may be electrically connected to the second dummy line through the first dummy line.

The display apparatus according to various embodiments of the present specification may further include a vertical connection line that is disposed in the display area, receives a data voltage, and extends in the second direction, in which the vertical connection line may be electrically separated from the second dummy line.

According to the display apparatus according to various embodiments of the present specification, the vertical connection line may be located on the same extension line as the second dummy line in the second direction.

The display apparatus according to various embodiments of the present specification may further include a horizontal connection line extending in the first direction, in which the horizontal connection line may be electrically connected to the vertical connection line.

The display apparatus according to various embodiments of the present specification may further include a data driving unit configured to generate the data voltage, in which the vertical connection line may electrically connect the data driving unit to the horizontal connection line.

According to the display apparatus according to various embodiments of the present specification, one of the initialization transistor, the driving transistor, and the data supply transistor may be a polycrystalline thin film transistor, and another one may be an oxide thin film transistor.

According to the display apparatus according to various embodiments of the present specification, all of the initialization transistor, the driving transistor, and the data supply transistor may be oxide thin film transistors.

According to the display apparatus according to various embodiments of the present specification, the anode reset line may include a first anode reset line disposed on the display area, and a second anode reset line disposed on the non-display area, and the dummy line may be connected to the first anode reset line.

According to the display apparatus according to various embodiments of the present specification, the second anode reset line may surround the display area and may be electrically connected to the first anode reset line.

A display apparatus including a display area that has a pixel including an anode electrode, and a non-display area located around the display area according to various embodiments of the present specification includes a substrate, a first conductive layer including an anode reset line that resets the anode electrode, and a second conductive layer disposed on the first conductive layer and including a vertical dummy line electrically connected to the anode reset line.

The display apparatus according to various embodiments of the present specification may further include a third conductive layer disposed between the first conductive layer and the second conductive layer, in which the third conductive layer may include a horizontal dummy line connecting the vertical dummy line to the anode reset line.

According to the display apparatus according to various embodiments of the present specification, the pixel may further include a light-emitting element including the anode electrode, an organic layer, and a cathode electrode, and an initialization transistor connecting the anode electrode to the anode reset line.

According to the display apparatus according to various embodiments of the present specification, the first conductive layer may further include a gate electrode of the initialization transistor, and the third conductive layer may further include a source electrode of the initialization transistor.

According to the display apparatus according to various embodiments of the present specification, the pixel may further include a driving transistor connected to the anode electrode, a data supply transistor that supplies a data voltage to the driving transistor, and a connection electrode connecting the driving transistor to the anode electrode.

According to the display apparatus according to various embodiments of the present specification, the second conductive layer may further include the connection electrode.

According to the display apparatus according to various embodiments of the present specification, the anode reset line may include a first anode reset line disposed on the display area, and a second anode reset line disposed on the non-display area, the dummy line may be connected to the first anode reset line, and the second anode reset line may surround the display area and may be electrically connected to the first anode reset line.

According to the display apparatus of the embodiments of the present specification, it is possible to improve image quality abnormality due to a change in anode reset voltage by connecting the dummy line to the anode reset line to reduce the resistance of the anode reset line.

According to the display apparatus of the embodiments of the present specification, it is possible to secure the spare space for a layout design using the dummy line formed during the same process as the connection line on the display area, thereby increasing the degree of freedom in design.

According to the display apparatus of the embodiments of the present specification, it is possible to omit the process for forming a separate low-resistance line for reducing the line resistance by reducing the line resistance of the anode reset line using the dummy line formed during the same process as the connection line on the display area.

According to the display apparatus of the embodiments of the present specification, it is possible to supply the data voltage to the pixels located outside the display area by connecting the data line connected to the data driving unit through the connection line on the display area. Accordingly, it is possible to implement the narrow bezel.

According to the display apparatus of the embodiments of the present specification, it is possible to reduce the resistance of the anode reset line by electrically connecting the dummy line formed during the same process as the connection line on the display area to the anode reset line, thereby reducing the power for driving the anode reset voltage and implementing low power. Accordingly, according to the display apparatus of the embodiments of the present specification, it is possible to reduce power consumption.

The display apparatus of the embodiments of the present specification includes the oxide transistor and needs to additionally have a shield structure for protecting the upper and lower portions of the oxide semiconductor of the oxide transistor. In this case, due to the additional arrangement of the shield structure, the width of the anode reset line can be narrowed, the ripple can be larger due to the increased resistance, and the node to which the data voltage is applied shakes, and image quality can be degraded. However, according to the embodiments, it is possible to reduce the resistance of the anode reset line by electrically connecting the dummy line formed during the same process as the connection line on the display area to the anode reset line. Accordingly, it is possible to prevent image quality from being degraded. In other words, the electrical connection between the anode reset line and the dummy line, in operation, reduces a ripple of an anode reset voltage applied to the anode electrode.

However, effects obtainable from the present specification are not limited to the above-described effects, and other effects that are not mentioned will be able to be clearly understood by those skilled in the art to which the present specification pertains from the following description.

Although one embodiment has been described above with reference to the accompanying drawings, those skilled in the art to which the specification pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the specification is described by the claims to be described below rather than the detailed description. In addition, the meaning and scope of the claims and all changed or modified forms derived from the equivalent concept should be construed as being included in the scope of the specification.

### DESCRIPTION OF REFERENCE NUMERALS

10: display apparatus
100: display panel
200: controller
300: gate driving unit
400: data driving unit
500: power supply unit
VAR_L: anode reset line
LIA_H: horizontal connection line
LIA_H_D: dummy horizontal connection line
LIA_V: vertical connection line
LIA_V_D: dummy vertical connection line

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a display area on which an image is displayed;
a non-display area adjacent to the display area;
a pixel in the display area, the pixel including an anode electrode;
an anode reset line configured to reset the anode electrode; and
a dummy line disposed in the display area,
wherein the anode reset line is electrically connected to the dummy line.

2. The display apparatus of claim 1, wherein the pixel further includes a light-emitting element including the anode electrode, an organic layer, and a cathode electrode, and an initialization transistor configured to connect the anode electrode to the anode reset line.

3. The display apparatus of claim 2, wherein the pixel further includes a driving transistor connected to the anode electrode, and a data supply transistor that is configured to supply a data voltage to the driving transistor.

4. The display apparatus of claim 1, wherein the dummy line includes a first dummy line extending in a first direction, and a second dummy line extending in a second direction overlapping the first direction, and the anode reset line is electrically connected to the second dummy line.

5. The display apparatus of claim 4, wherein the anode reset line is electrically connected to the second dummy line through the first dummy line.

6. The display apparatus of claim 4, further comprising a vertical connection line that is disposed in the display area, receives a data voltage, and extends in the second direction, wherein the vertical connection line is electrically separated from the second dummy line.

7. The display apparatus of claim 6, wherein the vertical connection line is located on the same extension line as the second dummy line in the second direction.

8. The display apparatus of claim 6, further comprising a horizontal connection line extending in the first direction, wherein the horizontal connection line is electrically connected to the vertical connection line.

9. The display apparatus of claim 8, further comprising a data driving unit configured to generate the data voltage, wherein the vertical connection line electrically connects the data driving unit to the horizontal connection line.

10. The display apparatus of claim 3, wherein one of the initialization transistor, the driving transistor, and the data supply transistor is a polycrystalline thin film transistor, and another one is an oxide thin film transistor.

11. The display apparatus of claim 3, wherein all of the initialization transistor, the driving transistor, and the data supply transistor are oxide thin film transistors.

12. The display apparatus of claim 1, wherein the anode reset line includes a first anode reset line on the display area, and a second anode reset line on the non-display area, and the dummy line is connected to the first anode reset line.

13. The display apparatus of claim 12, wherein the second anode reset line surrounds the display area and is electrically connected to the first anode reset line.

14. A display apparatus comprising:
a substrate including a display area and an adjacent non-display area, the display area having a pixel including an anode electrode;
a first conductive layer including an anode reset line that is configured to reset the anode electrode; and
a second conductive layer on the first conductive layer and including a vertical dummy line electrically connected to the anode reset line.

15. The display apparatus of claim 14, further comprising a third conductive layer disposed between the first conductive layer and the second conductive layer, wherein the third conductive layer includes a horizontal dummy line configured to connect the vertical dummy line to the anode reset line.

16. The display apparatus of claim 15, wherein the pixel further includes a light-emitting element including the anode electrode, an organic layer, and a cathode electrode, and an initialization transistor configured to connect the anode electrode to the anode reset line.

17. The display apparatus of claim 16, wherein the first conductive layer further includes a gate electrode of the initialization transistor, and the third conductive layer further includes a source electrode of the initialization transistor.

18. The display apparatus of claim 14, wherein the pixel further includes a driving transistor connected to the anode electrode, a data supply transistor that supplies a data voltage to the driving transistor, and a connection electrode configured to connect the driving transistor to the anode electrode.

19. The display apparatus of claim 18, wherein the second conductive layer further includes the connection electrode.

20. The display apparatus of claim 14, wherein the anode reset line includes a first anode reset line on the display area, and a second anode reset line on the non-display area, the vertical dummy line is connected to the first anode reset line, and the second anode reset line surrounds the display area and is electrically connected to the first anode reset line.

21. The display apparatus of claim 14, wherein the electrical connection between the anode reset line and the vertical dummy line, in operation, reduces a ripple of an anode reset voltage applied to the anode electrode.

22. A display apparatus comprising:
a substrate including a display area and a non-display area adjacent to the display area;
a pixel including a light-emitting element including:
an anode electrode,
a cathode electrode, and
an organic layer between the anode electrode and the cathode electrode;
an anode reset line configured to reset the anode electrode; and
a dummy line extending into the display area, the dummy line configured to connect to the anode reset line,
wherein the anode electrode, in operation, receives an anode reset voltage via the dummy line.

23. The display apparatus of claim 22, wherein the dummy line includes a dummy vertical connection line and a dummy horizontal connection line that overlap with each other, and
wherein the anode reset line is electrically connected to the dummy vertical connection line via the dummy horizontal connection line.

24. The display apparatus of claim 22, further comprising a contact hole,
wherein the contact hole electrically connects the anode reset line to the dummy line and passes through at least one insulating layer.

25. The display apparatus of claim 22, wherein the anode reset line is on a different layer than the dummy line.

26. The display apparatus of claim 22, wherein the anode reset line is configured to receive the anode reset voltage during a hold period of a Variable Refresh Rate (VRR) driving mode.

27. The display apparatus of claim 22, further comprising an initialization transistor configured to connect the anode electrode to the anode reset line,
wherein an electrical connection between the anode reset line and the dummy line, in operation, reduces resistance of the anode reset line and reduces ripple in the anode reset voltage during switching of the initialization transistor.

28. The display apparatus of claim 22, wherein the dummy line includes a plurality of dummy vertical connection lines and a plurality of dummy horizontal connection lines,
wherein the anode reset line is connected to only a portion of the plurality of dummy vertical connection lines of the plurality disposed in the display area.

29. The display apparatus of claim 28, wherein the connected portion of the plurality of dummy vertical connection lines is located in a central portion of the display area.

30. The display apparatus of claim 28, wherein the connected portion of the plurality of dummy vertical connection lines is located in an edge portion of the display area.

31. The display apparatus of claim 22, further comprising:
a data line; and
a connection line;
wherein the dummy line is on a same layer as either the data line or the connection line.
